(19) United States
(12) Patent Application Publication
(10) Pub. No.: US 2025/0006674 A1
(43) Pub. Date: Jan. 2, 2025

(54) METHODS AND STRUCTURES FOR LOW TEMPERATURE HYBRID BONDING

(71) Applicant: ADEIA SEMICONDUCTOR BONDING TECHNOLOGIES INC., San Jose, CA (US)

(72) Inventors: Cyprian Emeka Uzoh, San Jose, CA (US); Oliver Zhao, Sunnyvale, CA (US); Gabriel Z. Guevara, Gilroy, CA (US); Dominik Suwito, San Jose, CA (US); Rajesh Katkar, Milpitas, CA (US)

(21) Appl. No.: 18/497,585

(22) Filed: Oct. 30, 2023

Related U.S. Application Data
(60) Provisional application No. 63/511,442, filed on Jun. 30, 2023.

(51) Int. Cl. H01L 23/00

(52) U.S. Cl. CPC H01L 24/05; H01L 24/03; H01L 24/08; H01L 24/80; H01L 2224/03452; H01L 2224/03462; H01L 2224/03464; H01L 2224/035; H01L 2224/05026; H01L 2224/05082; H01L 2224/05109; H01L 2224/05111; H01L 2224/05118; H01L 2224/05124; H01L 2224/05139; H01L 2224/05144; H01L 2224/05147; H01L 2224/05155; H01L 2224/05157; H01L 2224/05164; H01L 2224/05166; H01L 2224/05169; H01L 2224/05171; H01L 2224/05176; H01L 2224/0518; H01L 2224/05181; H01L 2224/05184; H01L 2224/05541; H01L 2224/05571; H01L 2224/05573; H01L 2224/05609; H01L 2224/05611; H01L 2224/05618; H01L 2224/05624; H01L 2224/05639; H01L 2224/05644; H01L 2224/05647; H01L 2224/05655; H01L 2224/05657; H01L 2224/05664; H01L 2224/05666; H01L 2224/05669; H01L 2224/05671; H01L 2224/05676; H01L 2224/0568; H01L 2224/05681; H01L 2224/05684; H01L 2224/08145; H01L 2224/08225; H01L 2224/80357; H01L 2224/80379; H01L 2224/80896; H01L 2924/01006; H01L 2924/05042; H01L 2924/0544; H01L 2924/059

(57) ABSTRACT

A semiconductor element is provided with a micro-structured metal layer over conductive features of a hybrid bonding surface. The micro-structured metal layer comprises fine metal grain microstructure, such as nanograins. The micro-structured metal layer can be formed over the conductive features by providing a metal oxide and reducing the metal oxide to metal. The micro-structured metal layer can be formed selectively if the metal oxide is formed by oxidation. When directly bonded to another element, the micro-structured metal layer forming strong bonds at the bonding interface can substantially reduce annealing temperature.

### BACKGROUND

### Field

The field relates to direct bonding of microelectronics, and more particularly to hybrid bonding.

### Description of the Related Art

The microelectronics industry has experienced tremendous growth over the past decades. However, the thirst of the market for ever higher input/output (I/O) density and faster connection between chips has been unquenchable. This demand has driven integrated circuit (IC) system designs into 3D architectures. Solder bumps and micro-bumps can provide vertical interconnects between chips by using small metal bumps on dies as one form of wafer-level packaging. Hybrid bonding can provide a solution for superior density of interconnect features.

Hybrid bonding, such as the DBI® technology commercially available from Adeia of San Jose, CA, avoids the use of metal bumps, and instead connects dies in packages using direct metal-to-metal (e.g., copper-to-copper) conductive feature connections. In the bonding layer of each bonding element conductive features, such as metal contact pads, are embedded in a dielectric material. The hybrid bonding surface can be planarized by chemical mechanical polishing (CMP) and cleaned to remove particles and contaminants. Plasma activation can create active sites on the dielectric of the hybrid bonding surface of at least one of the two elements to be bonded. The two bonding elements are aligned precisely as they are brought together in a bonding equipment and the active sites on the bonding surfaces bond to each other. The dielectric bonding can be processed at room temperature. An annealing process can aid in bonding aligned conductive features, and can also strengthen bonds between the dielectric materials.

While hybrid bonding has greatly improved the ability to form high density and reliable connections between microelectronics, there remains a need to improve yield, reduce cost and/or reduce thermal budget consumption.

### BRIEF DESCRIPTION OF THE DRAWINGS

Specific implementations will now be described with reference to the following drawings, which are provided by way of example, and not limitation.

FIGS. 1-5 are schematic cross-sectional views illustrating an example process for fabricating a semiconductor element having metal grains on conductive features for hybrid bonding.

FIG. 6A is an SEM image of an upper surface of a copper contact pad.

FIG. 6B is an SEM image of an upper surface of a copper contact pad after an oxidation and reducing process.

FIGS. 7-9 are schematic cross-sectional views illustrating another example process for fabricating a semiconductor element having metal grains on conductive features for hybrid bonding.

FIGS. 10-12 are schematic cross-sectional views illustrating an example process for hybrid bonding an element having metal grains on conductive features with another element.

FIG. 13 is a schematic cross-sectional view of another example of a bonded structure, similar to that of FIG. 12.

FIGS. 14-15 are schematic cross-sectional views illustrating an example process of hybrid bonding a wafer having metal grains on conductive features to another wafer.

FIG. 16 is a schematic cross-sectional view of the bonded structure of FIG. 15 after singulation.

FIGS. 17-21 are schematic cross-sectional views illustrating an example process for hybrid bonding a wafer having metal grains on conductive features with a plurality of dies.

FIG. 22 is a schematic cross-sectional view of two microelectronic elements configured to be hybrid bonded together.

FIG. 23 is a schematic cross-sectional view of a bonded structure comprising the two microelectronic elements in FIG. 22.

### DETAILED DESCRIPTION

Annealing temperatures and annealing durations for forming direct conductor-to-conductor (e.g., metal-to-metal) bonding is of great importance in the fabrication of directly bonded components. Lower annealing temperatures and/or shorter annealing durations are desirable, for example, for reduced consumption of thermal budget and reduced stressed due to CTE mismatch. Various bonding layer structures and methods for producing such bonded semiconductor elements can be implemented to achieve lower annealing temperatures to sufficiently fuse contact pads or other conductive features of the bonded semiconductor elements together. One way in which annealing temperatures can be lowered includes providing a microstructure for the material of the conductive features, which can achieve bonding with lower annealing temperature. Providing conductive materials with microstructures, such as nanograins, can be expensive, however, and can also introduce greater contaminants into the conductors.

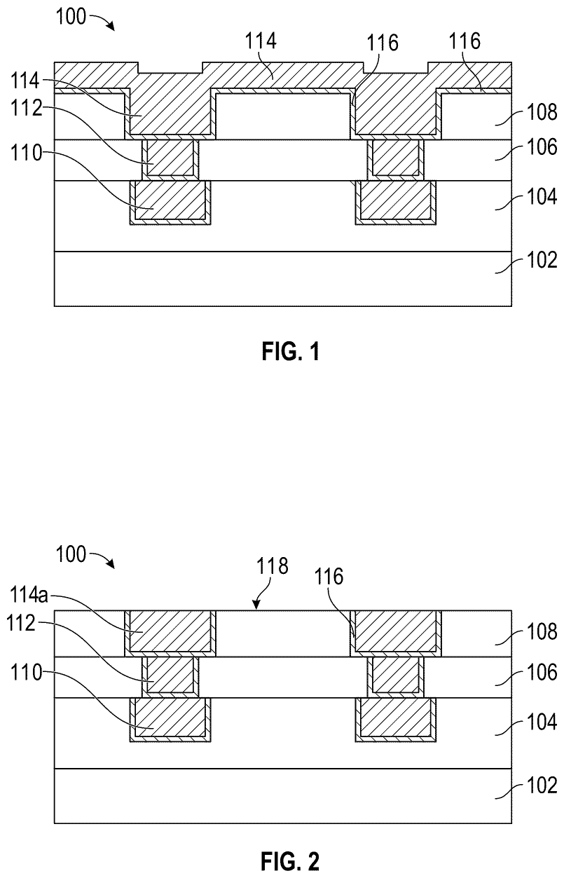

FIGS. 1-5 illustrate an example embodiment of a fabrication process for forming a microstructure for conductive features, such as contact pads. FIG. 1 shows a schematic cross-sectional view of at least a portion of a microelectronic structure 100, such as a semiconductor element, microelectronic element or a dielectric element. The microelectronic structure 100 can comprise a base substrate 102, such as a bulk semiconductor material (e.g., silicon), an interposer substrate, a semiconductor package substrate, a flat panel substrate, or a dielectric substrate. The base substrate 102 can comprise active circuitry and/or other devices formed at least partially therein. A base nonconductive or dielectric material layer 104 can be provided over the base substrate 102 with conductive features 110 embedded therein. A first nonconductive or dielectric layer 106 can be provided over the dielectric material layer 104. Intervening vias 112 can be embedded in the first dielectric layer 106. A second nonconductive or dielectric layer 108 can be provided over the first dielectric layer 106 and a patterned conductive material can be at least partially embedded therein to provide conductive features. In some embodiments, the conductive features can be provided by deposition and etching. In the illustrated embodiment, a stage of damascene processing is shown. Trenches are formed in the upper or second dielectric layer 108, which are then filled with a conductive material 114. The conductive material 114 may overfill the cavities, including an overburden over field regions of the second dielectric layer 108. A barrier layer 116 may be provided between the second dielectric layer 108 and the conductive material 114 to limit diffusion of the conductive material 114 into the second dielectric layer 108 and to serve as an adhesion layer between the conductive material 114 and the second dielectric layer 108. In some embodiments, separate adhesion and barrier layers may be provided prior to filling the damascene cavities.

In some embodiments, a seed layer may be disposed on the barrier layer 116, such as by copper sputtering. In some embodiments, the conductive material 114 and the intervening vias 112 are formed together, e.g., by a dual damascene process, in which case the barrier layer 116 can be omitted between the conductive material 114 and the intervening vias 112.

In FIG. 1 each of the first dielectric layer 106 and the second dielectric layer 108 can comprise an inorganic dielectric material, such as silicon oxide, silicon nitride, silicon oxynitride, silicon oxycarbonitride, etc. In some embodiments, one or both of the first dielectric layer 106 and the second dielectric layer 108 can be a low-k dielectric material, e.g., porous silicon oxide, organosilicate glass (SiCOH), or amorphous carbon. In still other embodiments, the dielectric layers may comprise polymeric materials. Each or any of the conductive features, including the intervening vias 112, the conductive material 114, and the underlying conductive feature 110 can comprise a metal, such as copper, nickel, chromium, gold, indium, tin, platinum, silver, ruthenium, molybdenum, palladium, cobalt, zinc, tungsten, tantalum, titanium, aluminum, a metal silicide, and alloys thereof, or a non-metal conductive material, e.g., doped silicon.

Referring to FIG. 2, the element 100 may go through an annealing process if desired to optimize grain structure of the conductive features. Subsequently, the excess conductive material 114 and the barrier layer 116 disposed on the top surface of the second dielectric layer 108, and possibly a top portion of the dielectric layer 108, can be removed to leave a planarized upper surface 118, such as by CMP. The planarization may be suitable for direct bonding, as described herein. After planarization, the conductive contact material portions 114 are confined in their isolated cavities, and thus become conductive features 114a, as shown in FIG. 2. The conductive features 114a can be conductive vias or contact pads or other conductive functional or nonfunctional features, such as dummy pads, lateral traces, or the upper ends of vias such as through substrate vias (TSVs).

The conductive features 110, 112, 114a may be characterized by a crystalline microstructure with grains. In general, average grain size of the crystalline structure of the conductive feature 110, 112. 114a may range from 0.2 μm to 5 μm or even larger. Factors that can influence grain size of the crystal structure in a conductive feature may include the width of the conductive feature, the impurity content in the conductive feature and the thermal history of the conductive feature. For example, grain size may be bigger for a wider conductive feature. For conventionally plated copper conductive features, for example, the impurity content is typically less than 20 ppm, e.g., less than 10 ppm.

In some embodiments, the conductive material 114 may be deposited over the first dielectric layer 106, patterned to form conductive material 114a. The second dielectric layer 108 is subsequently formed over dielectric layer 106 and embedding the patterned conductive material 114a,—forming a non-planar dielectric layer. The non-planar second dielectric layer 108 and the conductive features 114a can be planarized, e.g., with CMP methods, to form the smooth planar upper surface 118 suitable for direct bonding.

The upper surface 118 of the element 100 includes an upper surface of the second dielectric layer 108 and upper surfaces of the conductive features 114a. The top layer of the element 100, including the second dielectric layer 108 and the conductive features 114a of the illustrated embodiment, can be referred to as a hybrid bonding layer, and the upper surface 118 can be prepared to be directly bonded to another semiconductor element or dielectric element without an adhesive layer. The skilled artisan will appreciate that in other embodiments, the processes described herein can be applied to more complicated or simpler structures than shown in FIG. 2, such as greater or fewer metallization levels between the device level and the bonding layer. The skilled artisan will also appreciate that the processes and structures described herein are also applicable to non-IC microelectronic elements, such as, without limitation, passive devices, MEMS, interposers, other packaging substrates, etc.

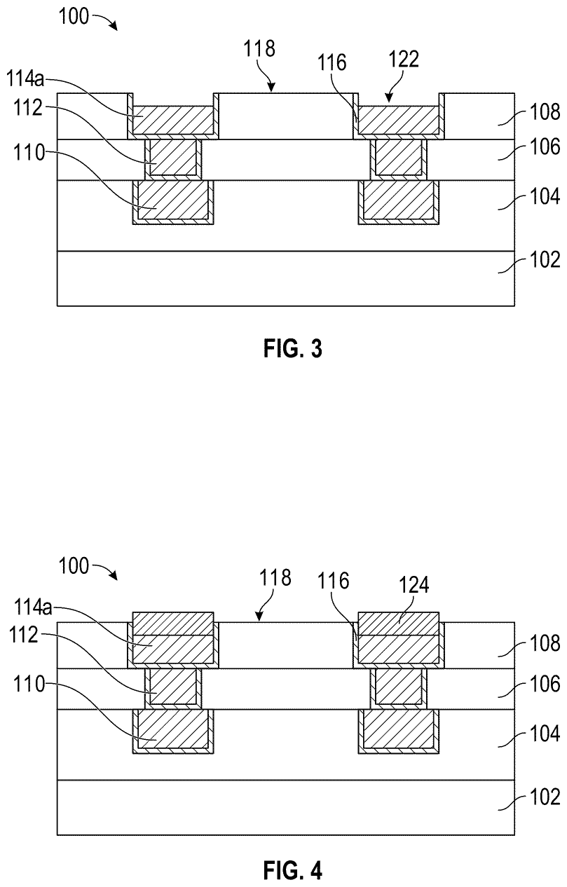

As shown in FIG. 3, top portions of the conductive features 114a are selectively removed (e.g., by etching) to form recesses 122. The depth of the recesses 122 can be between about 1 nm and 100 nm, for example, between about 3 nm and 80 nm, or between about 5 nm and 60 nm. In some embodiments, deeper recesses can be formed, e.g., between about 10 nm and 150 nm or even deeper, depending in part upon the structure of the conductive features 114a and the amount of underlying metal that can drive expansion. The skilled artisan will appreciate that the recesses 122 of FIG. 3 can be formed by a separate recessing operation after planarization and annealing, as shown, or can be the result of the CMP process described above with respect to FIG. 2 with proper selection of physical components (e.g., pad hardness, speed) and chemical components (e.g., selectivity of the slurry) to leave the conductive features 114a recessed as shown in FIG. 3. In some embodiments, instead of recessing, the conductive features 114a may protrude over the upper surface of the second dielectric layer 108. The thickness of the protrusion (not shown) can be between about 1 nm and 30 nm, for example, between about 3 nm and 20 nm, or between about 5 nm and 30 nm. In some embodiments, thicker protrusions can be formed, e.g., between about 10 nm and 50 nm or even thicker. In some embodiments, there is no recess nor protrusion, and the conductive features 114a are formed coplanar with the upper surface 118 of the second dielectric layer 108.

In FIG. 4, the element 100 has been exposed to an oxidation environment that oxidizes upper portions of the conductive features 114a. The oxidation process can be a plasma oxidization (e.g., by exposure to an oxygen-containing plasma), thermal oxidization, ozone exposure, or wet oxidation (e.g., by exposure to inorganic or organic peroxides). In an example, the element 100 of FIG. 3 can be subjected to an ashing process, in which products of oxygen-containing plasma are supplied to the element. Such a process is referred to as “ashing” because it is traditionally employed for burning off organic photoresist. As illustrated in FIG. 4, during the oxidation process, oxygen can react with the upper surfaces of the conductive features 114a. As such a metal oxide layer 124 forms on the conductive features 114a as a result of oxidation of a metal of the conductive feature 114a. The metal oxide layer 124 grown in such a manner tends to have a microstructure, for example, characterized by nanograins, that differs from the larger grain-sized microstructure of the conductive features 110, 112, 114a. For example, the nanograins may have an average grain size (e.g., average of maximum grain dimensions) in the range of about 2 nm to 100 nm, e.g., an average grain size in a range of about 5 nm to 60 nm, or in a range of about 8 nm to 80 nm. As shown in FIG. 4. the addition of oxygen into the layer and the growth of oxide with a microstructure (e.g., nanograins) may cause the resultant metal oxide layer 124 to protrude above the upper dielectric surface of the hybrid bonding layer. Also depending on the depth of the recess 122 or the height of the protrusion, the formed metal oxide layer 124 may be recessed below the upper surface 118, for example, by between about 2 nm to 10 nm or even more, or may protrude over the upper surface 118.

In the embodiment shown in FIG. 4, the metal oxide layers 124 are formed by oxidation of the upper surfaces of the conductive features 114a which comprise a metal. One advantage of oxidation is that the metal oxide layers 124 can be formed selectively on the conductive features 114a to controlled depth. However, metal oxide grains can be formed at the upper surface of the conductive features 114a in other ways. For example, the metal oxide layers 124 can be formed by sputtering (e.g., reactive sputtering) metal oxide grains onto the upper surfaces of the conductive features 114a. As an example, the metal oxide layers 124 can be formed by spin-coating metal oxide grains onto the upper surfaces of the conductive features 114a. As another example, the metal oxide layers 124 can be formed by electrolytic or electroless deposition methods, chemical vapor deposition (CVD) methods or atomic later deposition (ALD) methods. In such embodiments, separate patterning processes may be employed to either prevent formation of the metal oxide over the dielectric field regions, or to remove any metal oxide from over the dielectric field regions of the upper surface 118.

Each of the methods set forth above may produce different microstructures of the metal oxide grains in the metal oxide layers 124. For example, the oxidation process, as illustrated in FIG. 4, may cause metal oxide to grow from the existing upper surfaces of the conductive features 114a. As such, the microstructure of the metal oxide grains may carry unique signature of the grain forming process. Further, different oxidation agents, for example, products of in situ or remote oxygen plasma, thermal oxidation, wet chemical oxidation, or electrolytic oxidation, may cause different and unique signatures. If the oxide grains are deposited, whether by sputtering or by spin-coating, on the conductive features 114a to form the metal oxide layers 124, the microstructure of the metal oxide grains may show unique signature of the specific deposition process. Other processes, e.g., electrolytic methods or CVD methods, may have their unique signatures in the microstructures of the formed oxide grains. The metal oxide nanograins may be spherical, cubic, acicular, in the form of nanofibers, or other shapes.

In each of the methods described above, the size of the deposited metal oxide grains may be controlled through process control. The size or diameter of the metal oxide grains may be determined through routine experimentation, e.g., on the scale of nanometers, (e.g., an average size of a maximum dimension in a range of about 2 nm to 100 nm, in a range of about 5 nm to 60 nm, or in a range of about 8 nm to 80 nm), for desired results with respect to bonding conditions and yield.

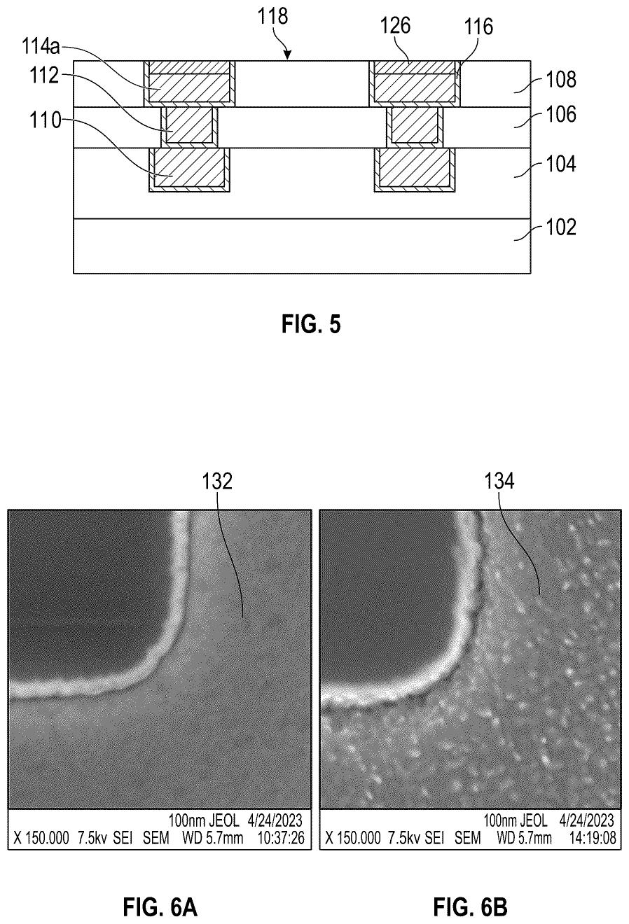

Referring to FIG. 5, the element 100 may be exposed to an environment to chemically reduce the metal oxide in the metal oxide layers 124 to a layer of metal grains or conductive material. The chemical reduction can be accomplished by exposure to a reducing ambient, such as, for example, hydrogen-containing plasma, water vapor plasma, hydrogen gas, or forming gas. Consequently, the metal oxide layers 124 may be at least partially transformed to a metal layer 126, as shown in FIG. 5. The metal layer 126 may take the form of nanograins and resemble a powder, flakes, needle like, or grains with spherical and non-spherical shapes. While shown with a reduced thickness relative to the metal oxide layers 124 of FIG. 4, the oxidation and reduction process nevertheless results in at least partial filling of the recess 122 because the microstructure of the resultant metal layer 126 may have reduced density relative to the metal prior to oxidation. In some embodiments, the reduced metal layer 126 with a microstructure (e.g., nanograins) may protrude over the upper surface 118.

For example, the metal oxide reduction process may comprise an annealing process in a reducing environment, such as with forming gas at an elevated temperature for a predetermined duration (e.g., at 25° C.-150° C. for 3 minutes to 90 minutes). The skilled artisan will appreciate that the temperature and duration of the reduction anneal may differ depending upon the reducing strength of the reducing environment. As such, the metal layer 126 can be at least partially sintered (or densified) if needed. The metal oxide reduction process may be accomplished under atmospheric pressure, in a reducing liquid or fluid, or in vacuum with a hydrogen ion bearing plasma. In one embodiment, the plasma may be hydrogen plasma, ammonia plasma, water vapor plasma, or a combination of helium or other inert gas and at least one of the mentioned reducing constituents. In one embodiment, the reducing source may comprise a liquid or fluid comprising dimethylamine borane or formic acid.

Experiments have been conducted to oxidize a copper surface of a contact pad by ashing (exposure to products of an oxygen-containing plasma) for 21 minutes, followed by reducing the resultant copper oxide to copper by annealing for 2 hours at 120° C. in the presence of forming gas. FIG. 6A is a scanning electron microscope (SEM) image showing an upper surface 132 of a copper contact pad in an element prior to oxidation and reduction process. As can be seen, the surface 132 is smooth. The experimental data shows that the upper surface 132 of the copper contact pad is recessed by about 16 nm with a surface roughness of about 1.2 nm RMS. In comparison, FIG. 6B shows an SEM image of an upper surface 134 of the copper contact pad following the oxidation and reduction process. The experimental data reveals that the upper surface 134 of the reduced copper surface is recessed by about 7.8 nm with a surface roughness of about 2.6 nm RMS. This means that the ashing process increases the roughness of the copper surface from about 1.2 nm RMS to about 2.6 nm RMS, while the recess of the surface decreases from 16 nm to 7.8 nm due to the formation of the copper oxide on the upper surface of the copper contact pad. The experimental data further shows that upon the reduction of the copper oxide, the upper surface 134 of the reduce copper oxide is recessed by about 8.9 nm with a surface roughness of about 2.2 nm RMS. The increased depth of the recess of upper surface 134 from about 7.8 nm to about 8.9 nm is indicative of densification of the reduction process. Similarly noted is the increase of the surface from about 1.2 nm RMS of the unoxidized upper surface 132 to about 2.2 nm RMS of the upper surface 124 after oxidation and reduction. Evidently, the upper surface 134 of the reduced metal pad is characterized by having a microstructure of ultra fine grains (e.g., nanograins). Measurements of the grains revealed that the size for the grains is in the range of about 5 nm-60 nm. For other metal materials, e.g., nickel, chromium, gold, indium, tin, platinum, silver, ruthenium, molybdenum, nickel, cobalt, palladium, zinc, tungsten, tantalum, titanium, aluminum, a metal silicide, and alloys thereof, used to make the contact pad, the grain size may be in a range of about 2 nm to 100 nm. The skilled artisan will appreciate that the roughness of the upper surface 134 of the reduced copper oxide depends on the oxidation process and the subsequent reduction process, including the reducing temperature.

While illustrated and discussed herein as a separate micro-structured metal layer 126 over the conductive features 114a, as shown in FIG. 5, the skilled artisan will appreciate that this description is a semantic choice and the metal layer 126 can be considered part of the conductive features 114a. In some embodiments, particularly where the metal layer 126 is formed by oxidation and reduction, the material of the metal layer 126 will be the same as that of the underlying conductive features 114a, and only the microstructure will differentiate the remainder of the conductive features 114a from the overlying metal layer 126. In other embodiments, particularly where the metal layer 126 is formed by metal oxide deposition and reduction, the metal layer 126 may be the same or may differ from the remainder of the conductive features 114a in both its microstructure and material composition, depending on the composition of the deposited metal oxide.

The microstructure of the metal layer 126 having ultra small metal grains may be favorable for hybrid bonding when compared to conventional microstructure of the metal, e.g., the conductive features 110, 112, 114a, as described above with respect to FIG. 2. For example, the crystalline structure of copper generally comprises large grains, e.g., typically larger than 200 nm or on the order of microns in size or even larger. The structure of copper contact pad surface shown in FIG. 6B, which is characterized by ultra small grains, e.g., nanograins, can achieve good quality direct contact pad to contact pad bonding at lower temperatures than copper contact pad without the illustrated microstructure. Without being limited by theory, it is believed that the microstructure left by the oxidation and reduction processes effectively increases diffusion and lowers the fusing temperature of a metal when compared to the same metal without the microstructure. Therefore, when two semiconductor elements are directly bonded together, if at least one of the elements has the conductive features 114a with the metal nanograins in the metal layer 126 as shown in FIG. 6B, the metal grains at the bonding surface 118 can be fused with the conductive features of the other semiconductor element at a lower annealing temperature, when compared with bonding two semiconductor elements without the micro-structured metal layer 126. Reduced depth of recesses after the oxidation and reduction processes, when compared to the recess depth just prior to the oxidation and reduction (from 16 nm to 8.9 nm in the example above for FIGS. 6A-6B), also confirms the resultant microstructure occupying greater volume than the same metal without the oxidation and reduction. The conducted experiments also indicate remarkably high yield and low electrical resistance for oxidized and reduced conductive features, despite employing lower annealing temperatures for forming the metal-to-metal bonds in hybrid bonding.

In practice, during an activation and/or termination process, the upper surface 118 or 218 or both may be exposed to nitrogen bearing plasma (for example nitrogen plasma, forming gas plasma, ammonia plasma, nitrogen containing water vapor plasma). As such, the upper surface 134 of FIG. 6B comprising reduced metal nanograins can adsorb more nitrogen atomic species or moieties compared conventional metal pads, such as the unoxidized and smooth upper surface 132. The higher nitrogen absorption may be due to the larger surface area of the metallic nanograins in layer 134. Upon hybrid bonding, after the high temperature annealing step, the bonded structure having reduced metal nanograins at bonding surface 134 may contain higher nitrogen content compared to bonded structure having smooth bonding surface 132. For example, the nitrogen content within a bonded structure having metal grain layers with the upper surfaces 134 may be at least 50 ppm or 500 ppm higher than the nitrogen content at equivalent locations in a bonded structure having contact pads with initially smooth upper surfaces 132. As such, the nitrogen content within the bonded conductive features of the presently disclosed bonded structures may be 50 ppm-1000 ppm and even 10000 ppm higher than conventional bonded structures. In some embodiments, the nitrogen content within the conductive features may be at least 250 ppm higher than the nitrogen content of the redistribution layer (RDL) or back end of line (BEOL) layer beneath the bonded conductive features. In some embodiments, the bonded conductive features may comprise oxygen or hydrogen content that are higher than the oxygen or hydrogen content of the RDL or BEOL layer beneath the bonded conductive features.

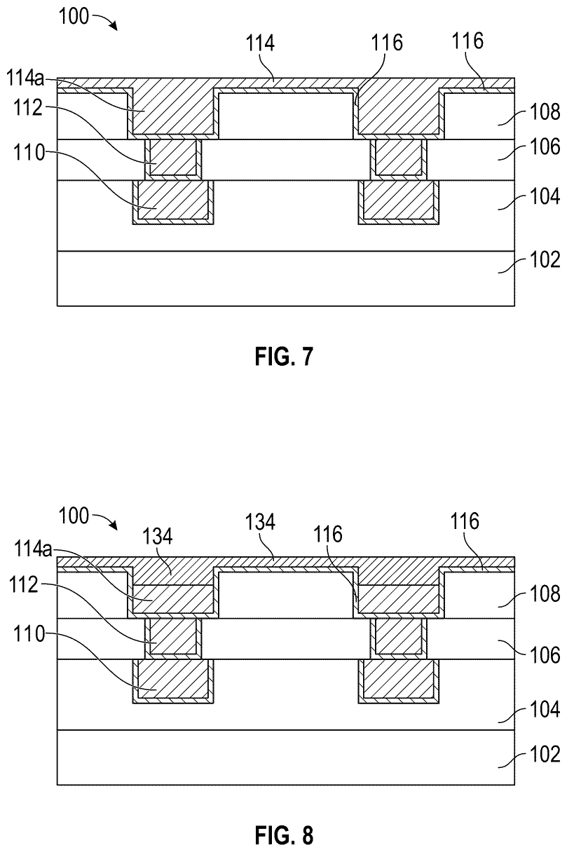

FIGS. 7-9 illustrate an example embodiment of another fabrication process to form a microstructure in contact pads favorable for a lower annealing temperature. Similar to FIG. 1, the process of FIGS. 7-9 starts with the element 100, having the conductive material 114 overburdening trenches formed in the second dielectric layer 108. The element 100 may be subjected to an annealing process. Subsequently, the excess conductive material 114 may be removed and planarized, e.g., by CMP. However, the planarization stops above the barrier layer 116 that is disposed on the upper surface of the second dielectric layer 108, leaving a thin layer of conductive material 114 above the barrier layer 116. Thus, the conductive material 114 is shown planarized in FIG. 7, but not fully removed from over the second dielectric layer 108.

Referring to FIG. 8, the element 100 is exposed to an oxidation environment to oxidize upper portions of the conductive material 114, including the thin layer of conductive material 114 on top of the barrier layer 116. As with FIG. 4, the oxidation process can be a plasma oxidation, thermal oxidization, ozone exposure, or wet or chemical oxidation. After oxidation, the upper portions of the conductive material 114, including the conductive material 114 on top of the barrier material 116 above the second dielectric layer 108, are oxidized, forming a metal oxide layer 134 into the upper portions of cavities formed in the second dielectric layer 108, as shown in FIG. 8. As with the metal oxide layers 124 in FIG. 4, the metal oxide layer 134 can comprise ultra small metal oxide grains, and may be considered nanograins. The ultra small metal oxide grains can thus have an average size in the nanometer range of about 2 nm-100 nm, about 5 nm-60 nm, or about 8 nm-80 nm.

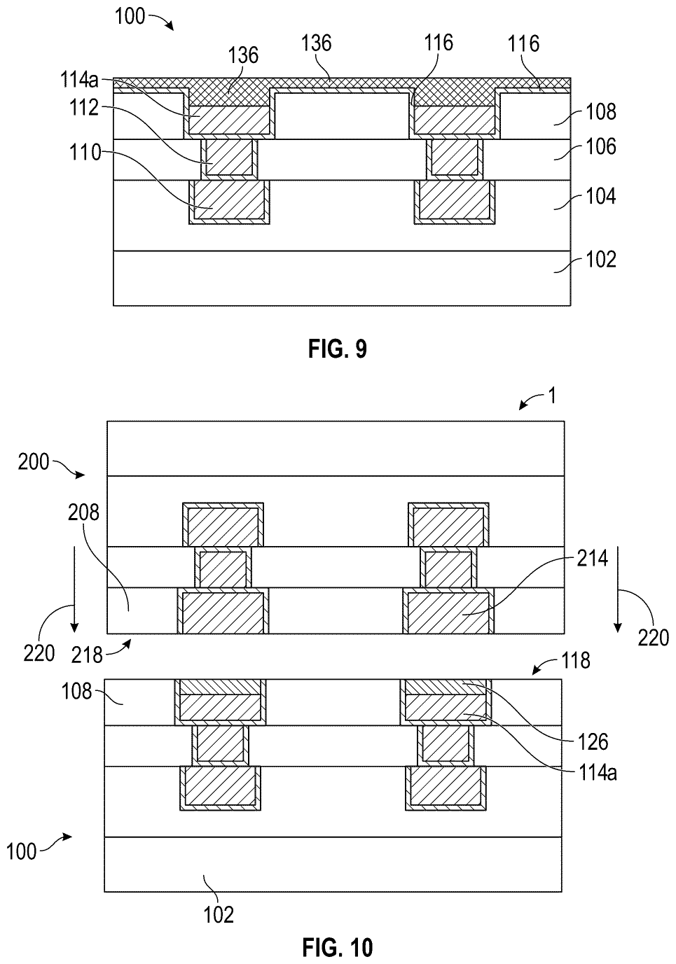

In FIG. 9, the element 100 may be exposed to an environment that chemically reduces all or a part of the metal oxide layer 134 to metal. The chemical reduction environment can be a reducing ambient, such as hydrogen plasma, water vapor plasma, hydrogen gas, or forming gas. As with respect to the metal layer 126 shown in FIG. 5, the metal oxide layer 134 may be transformed to a metal layer 136 comprising a microstructure, such as the nanograins described elsewhere herein. The reducing environment may range from vacuum to atmospheric pressure and may be performed in a range of about 10° C. to 180° C. such as about 20° C. to 100° C. Subsequently, the metal layer 136 can be at least partially sintered or densified if needed, e.g., through an annealing process at an elevated temperature for a predetermined duration. The metal layer 136 can comprise a nanostructure, such as nanograins, as described with respect to FIG. 5.

The element 100 shown in FIG. 9 may be planarized to remove the excess metal above the barrier layer 116 and the barrier layer 116 in the field regions, to achieve the cross-sectional structure of the element 100 of FIG. 5. The element 100 can be cleaned and prepared for direct bonding to another element. The preparation steps may comprise exposing either or both of the upper surfaces 118 and 210 of the respective substrate 100 and substrate 200 to nitrogen plasma, rinsing the bonding surfaces to remove any spurious deleterious particles, and drying the substrates before the bonding operation.

In other embodiments, the metal oxide layer 134 in FIG. 8 and the barrier layer 116 over an upper surface of the second dielectric layer 108 may be first planarized, e.g., by CMP methods, to form a planar bonding surface comprising a second dielectric upper surface and the conductive features 114a each with a segregated metal oxide layer comprising nanograins. Subsequently, the individual metal oxide layers on top of the respective conductive features 114a can be reduced to form respective metal layers.

Referring to FIG. 10, the first element 100 from FIG. 5 or 9 (after planarization) and a second element 200 are ready to be bonded to form a bonded structure 1. While the first element 100 comprises the metal layer 126, having a microstructure as a result of the oxidation and reduction process, on each of the conductive features 114a at the bonding surface 118, the second element 200 does not have such a metal layer with a microstructure on its conductive features 214. In other embodiments, the second element 200 can include metal layers having microstructures just like the first element 100. As shown in FIG. 10, the conductive features 214 of the second element 200 are aligned with the corresponding conductive features 114a of the first element 100. After alignment of the conductive features 114a, 214, the second element 200 is moved along a direction 220, e.g., operated by a bonding equipment, to be directly bonded with the first element 100.

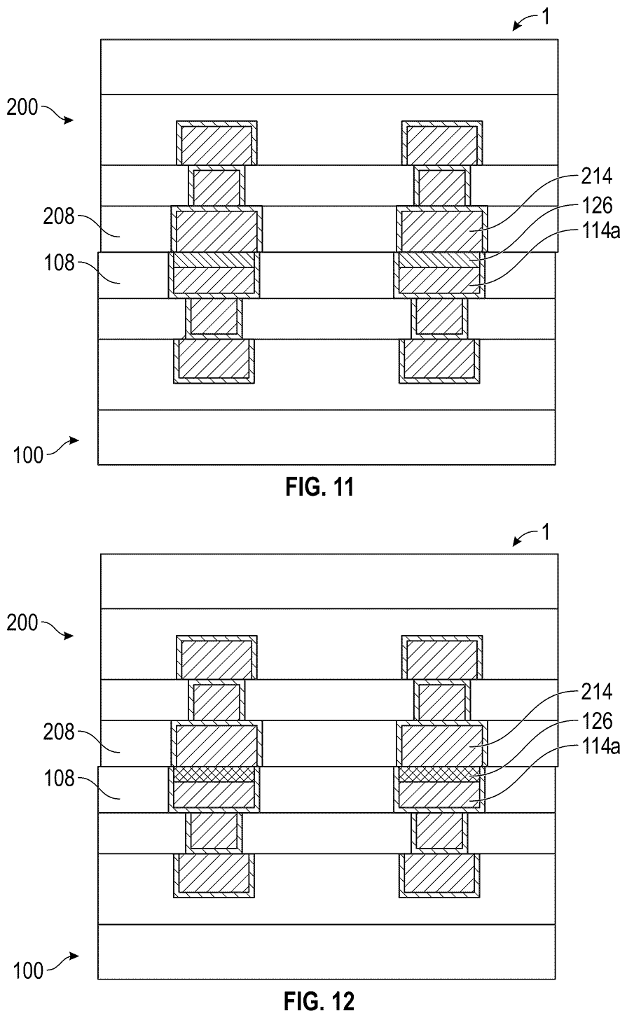

In FIG. 11, the second element 200 is directly bonded to the first element 100 without an intervening adhesive. The bonding surface 118 of the first element 100 and/or a bonding surface 218 of the second element 200 may be activated prior to the hybrid bonding process. As such the dielectric layer 208 of the second element 200 can be directly bonded to the second dielectric layer 108 of the first element 100. The initial direct bonding of the dielectric surfaces may be performed at room temperature. At this stage, the conductive features 214 of the second element 200 are not (fully) bonded to the conductive features 114a of the first element 100. In some embodiments, the conductive features 114a, 214 of both elements 100, 200 are recessed relative to their surrounding dielectric layers 108, 208 such that there is a gap between the corresponding conductive features 114a, 214 at the stage of FIG. 11.

Moving to FIG. 12, the bonded structure 1 is subjected to an annealing process to heat the bonded elements 100 and 200 to an elevated temperature for a predetermined duration. During the annealing process, conductive features 114a of the first element 100 can expand due to the CTE mismatch between the metallic material of the conductive features 114a (and any underlying metal features) and the surrounding second dielectric material 108. Also due to the CTE mismatch, the conductive features 214 of the second element 200 can have a tendency to expand. The expansion of the conductive features 114a, 214 causes the in situ formed nanograin metal layer 126 of the conductive feature 114a to press against and be bonded or fused with the corresponding conductive features 214 of the element 200. In some embodiments, the higher surface mobility of the nanograins metal layer 126 can lower the melting point due to the microstructure of the metal layer 126, facilitating interdiffusion across an initial interface with the conductive features 214. The interdiffusion and grain growth can increase the grain size of the nanograins metal layer 126 from nanometer scale to micron scale. The grain size at the bonding interface or across the bonding interface may range from 0.2 μm to more than 5 μm, depending on the width of the bonded conductive features, for example contact pads, upper ends of vias or TSVs.

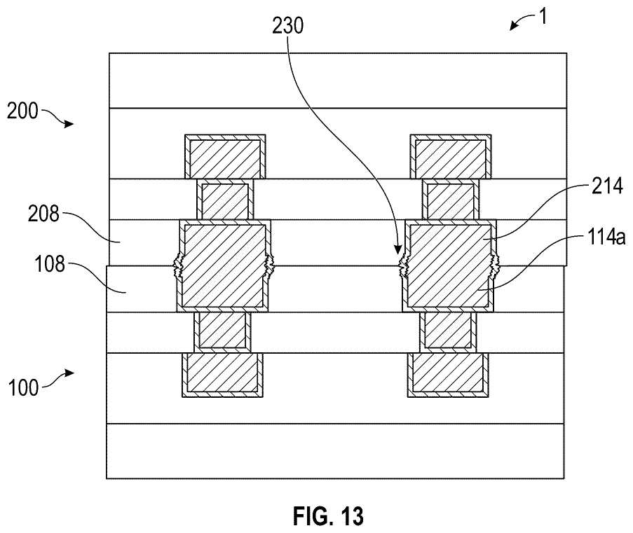

Experiments have shown that at certain annealing temperature and duration settings a continuous bonded region may be formed across the interface of the bonded elements. This bonded structure is illustrated schematically as the bonded region 230 in FIG. 13. In this way, mechanical bonding and electrical connection between the conductive features 114a of the first element 100 and the conductive features 214 of the second element 200 may be optimally established.

Referring to FIG. 13, due to the CTE mismatch between the conductive features and the surrounding dielectric materials, the conductive features 114a and the corresponding conductive features 214 are pressed against each other. The metal layer 126 of the conductive features 114a shown in FIG. 12 may be bonded or fused with the opposite conductive features 214. In some embodiments, the force developed from the CTE mismatch during bonding at the elevated annealing temperature may cause the conductive features 114a and 214 in the bonded region 230 at the hybrid bonding interface to swell outward, forming a sidewall structure bulging out sideways. In some embodiments, there may not be bulging sidewall at the bonding interface. The profile and the microstructure of the bonded region 230 may depend on the annealing temperature and the annealing duration, in addition to the microstructure between the conductive features at the time of bonding. As described earlier, the higher surface mobility of the metal layer 126 can lower the bonding or melting temperature of the metal layer 126, facilitating interdiffusion across the bonding interface with the conductive feature 214. The interdiffusion and grain growth may consume the nanograins, increasing the grain size of the nanograins of the metal layer 126 from nanometer scale to micron scale. The grain size at the bonding interface or across the bonding interface may range from 0.2 μm to more than 5 μm, depending on the width of the bonded conductive features, for example contact pads, upper ends of vias or TSVs.

The bonded conductive features 114a and 214 may have higher nitrogen content compared to bonding processes without micro-structured metal layers on conductive features. For example, the nitrogen content within a bonded structure applying the metal grain layers bonding principles may be at least 50 ppm or 500 ppm higher than the nitrogen content at equivalent locations in a bonded structure having contact pads without such nanograins or microstructure. In some embodiments, the nanograins in the reduced metal layer may melt at the bonding interface, fusing with the grains from the opposing bonding surfaces.

Whether any residual microstructural signature from the metal layer 126 remains in the bonded structure 1, differentiating grain structures at the interface from more remote locations of the conductive features 114a, 214, can depend upon the annealing temperature and duration.

As discussed above with respect to FIGS. 6A and 6B, the small grains left by the oxidation and reduction process can help achieve lower annealing temperature with good quality direct bonding of conductive features, when compared with bonding two semiconductor elements without the micro-structured metal layer 126. In some embodiments, optimal hybrid bonding can be achieved when both the first element 100 and the second element 200 have micro-structured surfaces for both of the conductive features 114a and 214. However, when either one of the first and second elements 100 and 200 includes a micro-structured metal layer on its conductive features 114a or 214, annealing temperature can be substantially reduced. For example, if the conductive features 114a of the first element 100 and the conductive features 214 of the second element 200 are both made of copper without a micro-structured (e.g., nanograin) layer between them, the annealing temperature may be 250° C. or higher to achieve equivalent resistance and yield. When one of the first and second elements 100 and 200 has micro-structures metal layers 126 on its conductive features 114a or 214, the annealing temperature may be reduced to below about 250° C., below about 200° C., or below about 180° C. For example, the anneal temperature for directly bonding the conductive features 114a to conductive features 214 can be reduced to temperatures in a range of about 150° C. to 250° C., 100° C. to 200° C., or 80° C. to 180° C. In some embodiments, the annealing process may be performed in a microwave oven. In this case, the microwave radiation frequency may be tuned to be absorbed by the conductive features, such as the conductive features 214, 114a and reduced metal layer 126. The localized absorption of the microwave radiation by metal layer 126 can induce locally improved mobility of metal from the conductive nanograins in the metal layer 126, thus bonding or fusing the metal layer 126 on the conductive feature 114a of the element 100 with the conductive feature 214 of the element 200. The localized metal atom mobility may consume the nanograins of metal layer 126 to form larger grains at the bonding interface or across the bonding interface. The skilled artisan will appreciate that during annealing process temperature is increased to facilitate diffusion of chemical elements without necessarily reaching the melting point of the materials of the bonded structure. The increased diffusion may transfer the conductive features at or near the bonding interface to a different crystal structure or phase and may fuse the conductive features together. In some embodiments, a portion of the metal layer 126 may by incorporated in a crystalline grain structure or grain boundary disposed around the bonding interface due to the increased diffusion.

The scale of temperature reduction for equivalent annealing effectiveness may be related to the size and material of the metal grains formed in the metal layer 126. For example, the annealing temperature for metal grains sized 10 nanometers may be significantly lower than the annealing temperature for metal grains sized 50 nanometers.

One of the thermal challenges of hybrid bonding is bonding of conductive features having varying widths. For example, the bond temperature (or annealing temperature) for bonding substrates having conventional copper contact pads with widths of 10 μm to 50 μm may be about 250° C. However, the bonding temperature for narrower conventional copper contact pads (e.g., with widths of 0. 3 μm to 2 μm) may be higher and may range from 375° C. to 400° C. During annealing the thermal expansion of copper features within damascene cavities with widths or pitches smaller than 10 μm is smaller than thermal expansion of the copper features with widths or pitches greater than 10 μm. With few exceptions, the smaller the width of the damascene conductive structure, the smaller the thermal expansion during anneal, thus calling for higher anneal temperatures. One of the advantages of having metal nanograins in the metal layer 126 is that the bonding temperature may be less dependent upon the widths or pitches of the conductive features. Thus, the conductive features 114a of the element 100, comprising contact pads, dummy pads, lateral traces, upper ends of vias or TSVs, and/or other through substrate conductors, having widths or pitches ranging from 0.05 to 50 μm, having nanograin layers 126 formed thereon, can be bonded below 300° C. or even below 250° C. In some embodiments, the bonding surface 118 or 218 or both comprises conductive features (e.g., contact pads, dummy pads, lateral traces, vias, and/or through substrate conductors) may have widths or pitches ranging between 0.05 μm and 100 μm (e.g., between about 0.25 μm and 50 μm, or between 1 μm and 40 μm). These conductive features 114a exposed at the bonding surfaces 118 or 218 may comprise the metal layers 126 having nanograins for lower and consistent bonding temperature or annealing temperature. In some embodiments a thin layer of a second conductive material having nanograins may be coated over or incorporated in the conductive features 114a or 218.

One of the advantages of bonding elements or substrates with nanograin microstructure of the present disclosure is that substrates with large difference in CTEs can be bonded at lower temperatures. A first element or substrate with a CTE of X1 and comprising conductive features with a width less than 10 μm at its bonding surface can be bonded to a second substrate with a CTE of X2 (e.g., where X2 is greater than X1 by at least 4 ppm/° C.) at temperatures from 100° C. to 250° C. (e.g., from 125° C. to 240° C.) as opposed to 350° C. to 400° C. when the first substrate and the second substrate have small or no difference in CTEs. The lower temperature bonding reduces the stress related to large CTE mismatch. In some embodiments, the bonding surfaces of the first and second substrates having different CTEs can comprise conductive features (pads, traces, vias, TSVs, etc.) having widths less than 50 μm, e.g., less than 10 μm. In some embodiments, the bonding surfaces of the first and second substrates having different CTEs can comprise conductive features (pads, traces, vias, TSVs, etc.) having pitches less than 150 μm, e.g., less than 50 μm, less than 10 μm.

In some embodiments, the conductive features 114a of the first element 100 of FIG. 5 can comprise a first metal material, e.g., copper, nickel, gold, indium, molybdenum, cobalt, zinc, tungsten, tantalum, or titanium, aluminum, manganese, magnesium, palladium, tin, silver, indium, gallium, or alloys thereof; and the conductive features 214 in the second element 200 can comprise a second metal material from the same list of materials listed above. In this way, the first metal material of the conductive features 114a and the second material of the conductive features 214 can be made of the same metal material or different metal materials. In either case, a micro-structured metal layer 126 may be formed according to the processes described with respect to FIGS. 1-9 on the conductive features 114a and having the same metallic material as the conductive features 114a. The metal layer 126 can substantially reduce the bonding or annealing temperature. In some embodiments, the metal material forming the conductive features 114a and the conductive features 214 may be a high melting point metal with melting point higher than copper, e.g., cobalt or molybdenum. The metal layer 126 can be formed on the conductive features 114a and having the same metallic material as the conductive features 114a to substantially reduce the annealing temperature. In other embodiments, for example where a metal oxide layer is deposited and then reduced (as opposed to grown by oxidation and reduced), the metal of the micro-structured metal layer 126 can be different from the metal of the conductive features 114a on which it is formed.

In some high temperature implementations, the conductive features of a second element having a metal or non-metal conductive material with a melting point higher than that of copper (e.g., about 1083° C.) can be bonded to the metal layers 126 in the first element. For example, the conductive material with melting point higher than copper may be molybdenum, cobalt, tungsten, tantalum, titanium, manganese, nickel, palladium, platinum, rhodium, carbon, or their respective high temperature alloys. The metal layers 126 in the first element may comprise nanograins of the high melting point metal or non-metal material of the conductive features of the second element. In some embodiments, the composition of the metal layers 126 may be different from that of the conductive features of the second element the metal layers 126 to be bonded to. For example, the metal layers 126 comprising copper nanograins may be bonded to a conductive nickel contact pad of the second element at about 250° C. Upon bonding, the copper nanograins of the metal layer 126 can be inter diffused with the nickel contact pad to form a nickel copper alloy at the bonding interface. The skilled artisans will appreciate that a conductive material with a high melting point may require a higher annealing temperature. In some embodiments, each of the bonding layers 126 forms an alloy with the conductive feature of the bonded second element.

In some embodiments, the metal layers 126 may be configured to facilitate bonding dissimilar first and second conductive features. For example, the composition of the bonding metal layers 126 may be different from those of the conductive features 114a, 214 of the first and second element 100, 200 to be bonded. In some embodiments, the metal layers 126 comprising copper nanograins may be formed on the conductive features 114a of the first element 100, and bonded to the conductive features 214 of the second element 200 at about 250° C. (including the annealing process). For example, the metal layers 126 comprising copper nanograins may be formed on the first conductive features 114a comprising nickel. Subsequently, the metal layers 126 may be bonded to the second conductive features 214 comprising cobalt at a temperature less than 300° C., e.g., less than 250° C. (including the annealing process). The melting point of the metal layers 126, which comprises copper, is substantially lower than a melting point of the first conductive features 114a, which comprises nickel, and a melting point of the second conductive features 214, which comprises cobalt. Without the nanograin bonding layers 126, bonding dissimilar conductive features comprising nickel and cobalt could entail anneal at temperatures higher than 370° C., e.g., higher than 400° C. In some embodiments, for example, the metal layers 126 comprising copper, nickel, or cobalt, or combinations thereof, that have nanograin microstructure may be formed on the first conductive features 114a comprising tungsten or molybdenum, and subsequently bonded to the second conductive feature 214 comprising tungsten or molybdenum at a temperature less than 375° C., e.g., less than 325° C. (including annealing process). In this case, without the nanograin bonding layer 126, significantly higher temperatures, such as higher than 800° C., e.g., higher than 1000° C. may be needed to accomplish metal bonding, which may not be feasible for hybrid bonding many devices due to limited thermal budgets.

To the extend both elements 100, 200 to individual device dies, the process illustrated in FIGS. 10-13 can represent die-to-die (D2D) hybrid bonding involving a micro-structured metal layer at the bonding interface. The micro-structured metal layer can also be applied to wafer-to-wafter (W2W) hybrid bonding and die-to-wafer (D2W) hybrid bonding to reduce annealing temperature.

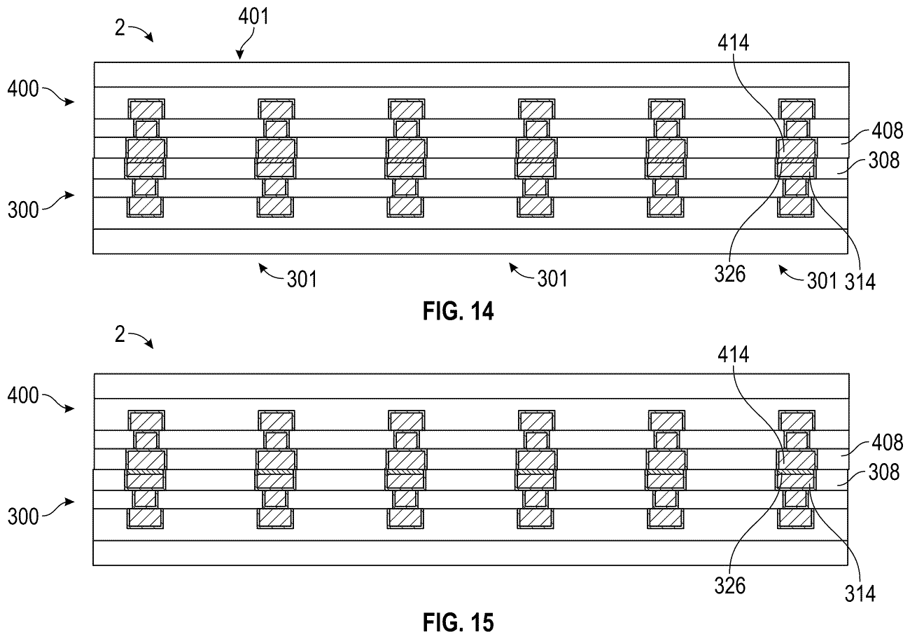

FIGS. 14-15 illustrates a hybrid bonding process to bond two wafer elements 300 and 400 together to form a W2W bonded structure 2. In FIG. 14, the element 300 is a wafter that includes a plurality of die modules 301 that may be identical to each other. The plurality of die modules 301 may also not be identical to each other but may be arranged in the first wafer element 300 for subsequent singulation. Each of the die modules 301 includes one or more contact pads 314 (or other conductive features configured for contacting other conductive features) that are embedded in a dielectric layer 308. A micro-structured metal layer 326 is shown on each contact pad 314 at the bonding surface of the first wafer element 300. The metal layer 326 may comprise ultra small metal grains, e.g., nanograins. FIG. 14 also shows the second wafer element 400 that includes a plurality of die modules 401, with each of the die modules 401 facing a corresponding die module 301 of the first wafer element 300. Each of the die modules 401 includes one or more contact pads 414 that are embedded in a dielectric layer 408. Both of the wafer elements 300, 400 are sufficiently planarized for direct bonding. One or both of the wafer elements 300, 400 may be activated, and the wafer elements 300, 400 are bonded together. In the illustrated embodiment, only the first wafer element 300 is provided with the micro-structured metal layer 326 on its contact pads 314; in other embodiments, such a micro-structured metal layer can be provided on the contact pads of both wafers.

Referring to FIG. 15, the bonded structure 2 including the wafer elements 300 and 400 may go through an annealing process at an elevated temperature for a predetermined duration. As explained with respect to FIG. 12, during the annealing process, due to the CTE mismatch between the metallic material of the contact pads 314, 414 and the surrounding dielectric material 308, 408, each contact pad 314, 414 can expand. As such, the contact pads 314, 314 are bonded or fused with the metal layer 326 therebetween. The microstructure of the metal layer 326 can lower the bonding temperature and facilitate interdiffusion and grain necking between the contact pads 314, 414, as described above with respect to FIGS. 5-6B. The bonding between the metal layer 326 on the contact pads 314 and the contact pads 414 may result in a continuous bonded region 230, as shown in FIG. 13. As such, good quality bonding and electrical connection between the contact pads 314 of the first wafer element 300 and the contact pads 414 of the second wafer element 400 may be established. Residual signatures of the metal layers 326 may or may not remain in the bonded structure 2 after annealing, depending upon the annealing conditions and whether the metal layers 326 were formed by reducing oxide of the same metal(s) or different metal(s) from that or those of the contact pads 314.

As discussed above when at least one of the wafer elements 300, 400 includes a micro-structured metal layer over its respective contact pad 314, 414, the bonding or annealing temperature can be substantially reduced. In some embodiments, the bonding surface of substrate 300, 400 or both comprises metal layers 326 over conductive features 314 (contact pads, dummy pads, lateral traces, vias, through substrate conductors) having widths or pitches in the range between about 0.05 μm and 100 μm (e.g., between about 0.25 μm and 50 μm or between about 1 μm and 40 μm). The metal layers 326 exposed at the bonding surface can comprise conductive metal nanograins as described herein. In some embodiments a thin layer of a second conductive material (not shown) may be coated over or incorporated in the metal nanograins layers 326. The metal layers 326 may comprise an alloy, for example an alloy comprising copper, tin, indium, gallium, aluminum, manganese, zinc magnesium, gold, palladium, platinum, or nickel. In some embodiments, the conductive features 414 of the element may comprise a second nanograin metal layer formed thereon (not shown).

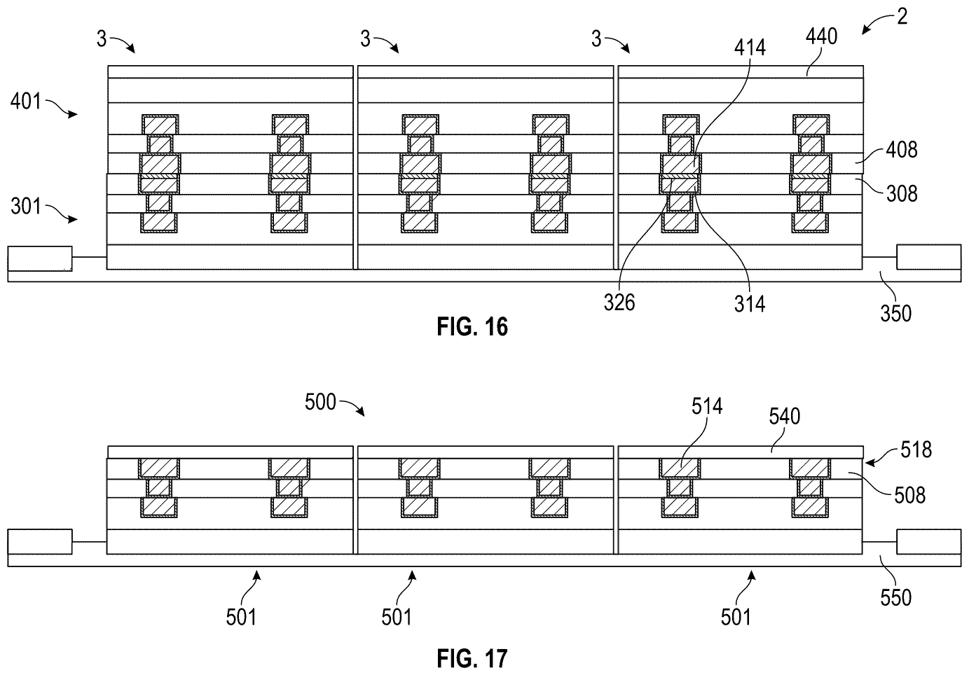

As shown in FIG. 16, a top surface of the W2W bonded structure 2 may be coated with a protective layer 440. In some embodiments, the bonded structure 2 may be coated with a top protective layer 440 on the top surface and a bottom protective layer (not shown) on a bottom surface of the bonded structure 2 contacting a dicing sheet 350. Subsequently, the bonded structure 2 may be singulated, e.g., by mechanical dicing, e.g., sawing, laser dicing, or plasma dicing, to separate the plurality of bonded modules 3. Sidewalls of individual dies 301, 401 of the bonded modules 3 will be flush with one another, as they are formed by a common singulation process. In FIG. 16, during the singulation process the bonded structure 2 may be supported by the dicing sheet 350. The singulated bonded structure 3 with the protective layer 440 is cleaned to remove the protective layer 440 and other unwanted debris from the top and bottom surfaces and sides of singulated modules 3 and the dicing sheet 350. The cleaning step may comprise stripping off the protective layer 440 with a suitable solution or solvent. For example, a resist stripper or developer may be applied to dissolve the protective layer 440. The stripping step may be followed by a rinsing step, for example, rinsing the plurality of singulated bonded modules 3 and the dicing sheet 350 with deionized (DI) water or other liquids and drying the cleaned bonded modules 3 the dicing sheet 350. The drying step may comprise, for example, spin-drying the singulated bonded structure 2. The bottom protective layer (not shown) maybe removed in subsequent processes.

FIGS. 17-21 illustrates a hybrid bonding process to bond dies to a wafer for D2W bonding. Referring to FIG. 17, a wafer element 500 comprises a plurality of die modules that may be identical to each other or not identical to each other but can be arranged for subsequent singulation. Each of the die modules may include one or more contact pads 514 (or other conductive features) that are embedded in a dielectric layer 508, and may be recessed relative to the dielectric layer 508 as disclosed herein. As shown in FIG. 17, the wafer element 500 is supported by a dicing sheet 550 and is coated with a protective layer 540. Subsequently, the wafer element 500 is singulated, e.g., by mechanical dicing, laser dicing, or plasma dicing, to separate the plurality of die modules into dies 501. In some embodiments, both top and bottom sides of the substrate 500 may be coated with the top protective layer 540 and a bottom protective layer (not shown) that can contact the dicing sheet 550 during the singulation step. At this point, the plurality of die modules are supported by the dicing sheet 550, keeping the original lateral positions relative to each other. In some embodiments, the upper surface 518 of the wafer element 500 may be activated before coating of the protective layer 540. In some embodiments, the upper surface 518 of the wafer element 500 may be not activated before the coating process.

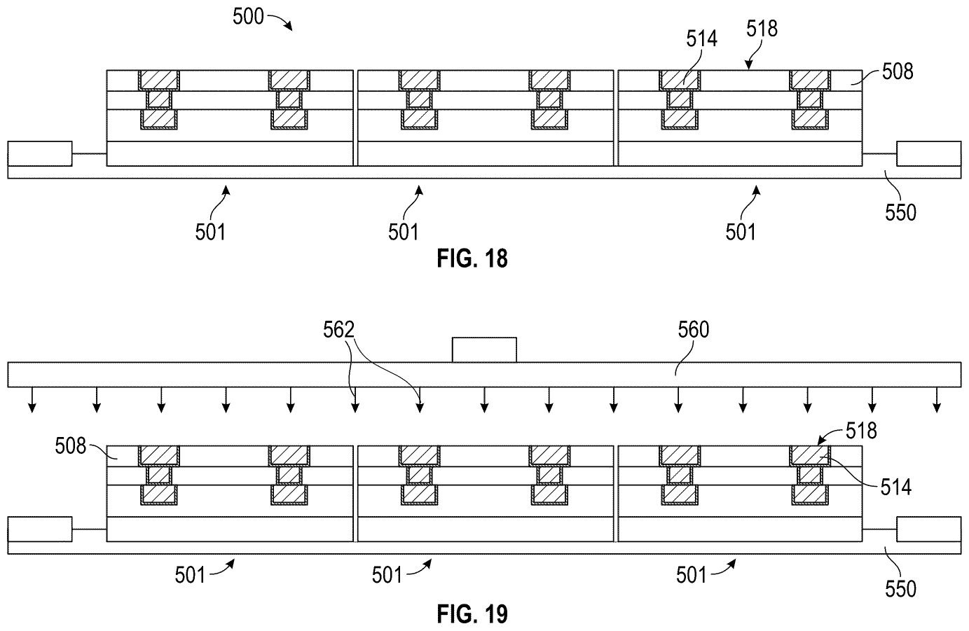

In FIG. 18, the protective layer 540 is stripped, exposing the upper bonding surface 518 of each singulated die 501. The singulated dies 501 with the protective layer 540 is cleaned to remove the protective layer 540 and other unwanted debris from the surfaces and sides of singulated dies 501 and the dicing sheet 550. The cleaning step may comprise stripping off the protective layer 540 with a suitable solution or solvent, as stated above. The stripping step may be followed by a rinsing step, for example, rinsing the singulated dies 501 and the dicing frame 550 with DI water or other liquids and drying the cleaned substrates. The drying step may comprise, for example, spin-drying the singulated dies 501 and the dicing frame 550. The bottom protective layer (not shown) maybe removed in subsequent processes.

Note that the individual die modules may have been tested using probe pads of the wafer element 500 prior to singulation to form the dies 501, or may be tested after singulation and removal of the protective layer 540, such that only known good dies (KGD) are employed in the subsequent bonding.

In FIG. 19, the plurality of dies 501 mounted on the dicing sheet 550 may be prepared for direct bonding. The preparation may comprise the previously described cleaning, rinsing and drying. The preparation steps may further include exposing the bonding surface to an activation process to activate the upper surface 518 of each die 501 if the upper surface 518 is not already activated. The activation process may include exposing the plurality of dies 501 to products of a plasma 562 (e.g., remote or in situ oxygen-containing and/or nitrogen-containing plasma) in a treatment chamber 560 for a period of time. Subsequently the die modules 501 may be rinsed and dried.

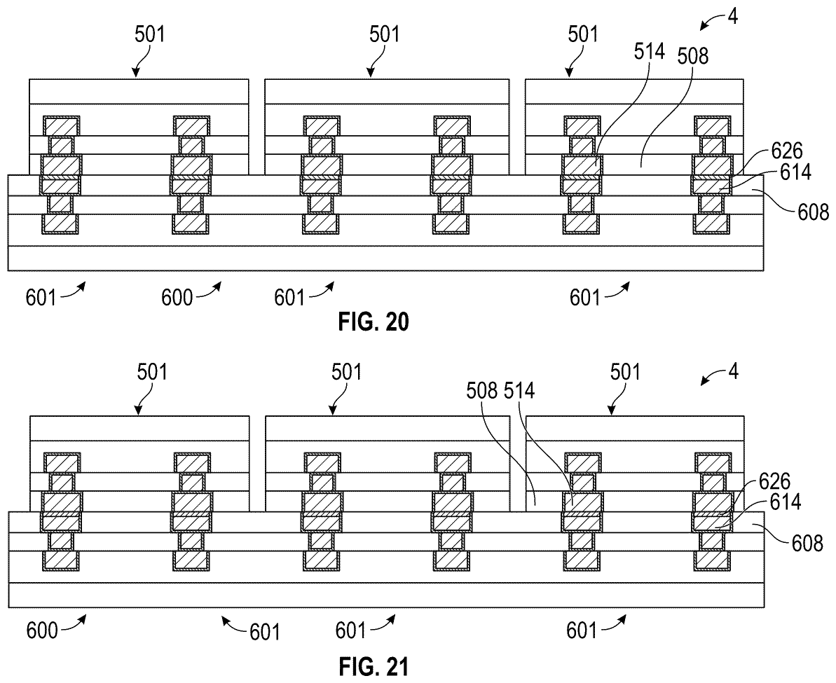

In FIG. 20, the plurality of dies 501 may be individually picked and placed at corresponding die modules 601 of a host wafer element 600, forming a temporary bond. Alternatively, the dies 501 may be mounted to a carrier and “gang” placed on the wafer 600 with individual die 501 aligned with individual die module 601. At this point a dielectric layer 508 of each die 501 is initially bonded to a dielectric layer 608 of a corresponding die module 601 the wafer element 600. Each die module 601 of the element 600 includes one or more contact pads 614 that are embedded in a dielectric layer 608. As described with respect to the first wafer element 300 of FIG. 14, a micro-structured metal layer 626 in provided on each contact pad 614 at the bonding surface of the die modules 601, e.g., selectively formed by oxidation and reduction, for hybrid bonding. The metal layer 626 may comprise ultra small metal grains, e.g., nanograins. The initial bonding of the dies 501 to the wafer element 600 can be conducted at room temperature, and aligned contact pads 514, 614, including the intervening metal layer 626, can still have gaps between them at this stage.

In some embodiments, each of the plurality of dies 501 may comprise at least a TSV or a through substrate conductive feature exposed on the back surface of the die 501 that is opposite to the bonding surface. The back surfaces of the dies 501 may be cleaned and dried. The back surfaces of the dies 501 may be prepared for bonding. For each of the dies 501, an additional die having TSV conductive features may be bonded on the prepared back surface to form a two-die stack over the wafer element 600 after hybrid bonding. In some embodiments, the stacked dies may comprise 3, 4, 5, and up to 20 dies stacked on top of each other over the wafer element 600 after hybrid bonding. The bonded stacked structure of dies may be annealed to bond the various conductive features in the stacked structure. In some embodiments each of the dies 501 may have micro-structured metal layer formed over contact pads 514 at their bonding surfaces.

Referring to FIG. 21, the D2W bonded structure 4 including the dies 501 and the wafer element 600 is subjected to an annealing process at an elevated temperature for a predetermined duration. As described with respect to FIG. 12 and FIG. 15, during the annealing process, due to the CTE mismatch between the metallic material of the contact pads 514, 614 and the surrounding dielectric material 508, 608 each contact pad 514, 614 can expand. Accordingly, the contact pad 614 is pressed against and bonded/fused with the corresponding contact pad 514 with the micro-structured metal layer 626 therebetween. The metal layer 626 substantially lowers the anneal temperature for metal-to-metal bonding and encourages interdiffusion and resultant grain necking across the interface, as described above with FIGS. 5-6. The bonding between the metal grain layer 626 and the contact pad 514 may result in a continuous bonded region, as discussed with respect to FIG. 13. As such, good quality bonding and electrical connection between the contact pads 614 of the wafer element 600 and the contact pads 514 of the wafer element 500 may be established. As discussed above, when at least one of the wafer element 600 and the wafer element 500 (e.g., the die modules 501) includes a micro-structured metal layer in each respective contact pad 514 or 614, annealing temperature can be substantially reduced. Residual signatures of the metal layer 626 may or may not remain in the bonded structure 4 after annealing, depending upon the annealing conditions and whether the metal layers 626 were formed by reducing oxide of the same metal(s) or different metal(s) from that or those of the contact pads 614.

Subsequently, the bonded structure 4 may be singulated, e.g., by mechanical dicing, laser dicing, or plasma dicing, to separate into the plurality of bonded modules, each comprising a die 501 and die module 601 hybrid bonded together. Each singulated bonded module can be similar to a D2D bonded structure 1 of FIG. 12. In some embodiments, after singulation, for each bonded module the die 501 may be smaller than the corresponding die module 601 of the host wafer element 600. In some embodiments, the backside of the wafer element 600 maybe coated with a protective layer (not shown), the backside protective layer contacting the dicing sheet (not shown) that supports the wafer element 600. After the dicing or singulation step, the singulated bonded structure is cleaned to remove the protective layer and other unwanted debris from the surfaces and sides of singulated bonded D2W structure and the dicing sheet (not shown). The cleaning step may comprise stripping off the protective layer with a suitable solution or solvent. For example, a resist stripper or developer may be applied to dissolve the protective layer. The stripping step may be followed by a rinsing step, for example, rinsing the singulated bonded structure and the dicing sheet with DI water or other liquids and drying the cleaned bonded structure. The drying step may comprise, for example spin-drying the singulated bonded structure and the dicing sheet.

Although shown and discussed with the example of semiconductor dies and wafers, the skilled artisan will appreciate that the micro-structured layer of metal on contact pads in a hybrid bonding layer, can be provided for other types of microelectronic elements. For example, such microelectronic elements may include an interposer, a semiconductor package, a flat panel, a dielectric substrate, surface mount devices, passive devices, MEMS devices, etc.

A die or a chip can refer to any suitable type of integrated device die. A wafer is a thin slice of material usually in a round shape for semiconductor device fabrication. After fabrication processes a wafer in general can include a plurality of dies formed thereon. For example, the integrated device dies can comprise an electronic component such as an integrated circuit (such as a processor die, a controller die, or a memory die), a microelectromechanical systems (MEMS) die, an optical device, or any other suitable type of device die. In some embodiments, the electronic component can comprise a passive device such as a capacitor, inductor, or other surface-mounted device. Circuitry (such as active components like transistors) can be patterned at or near active surface(s) of the die in various embodiments. The active surface may be on a side of the die which is opposite the backside of the die. The backside may or may not include any active circuitry or passive devices.

An integrated device die can comprise a bonding surface and a back surface opposite the bonding surface. The bonding surface can have a plurality of conductive bond pads including a conductive bond pad, and a non-conductive material proximate to the conductive bond pad. In some embodiments, the conductive bond pads of the integrated device die can be directly bonded to the corresponding contacts of the substrate or wafer without an intervening adhesive, and the non-conductive material of the integrated device die can be directly bonded to a portion of the corresponding non-conductive material of the substrate or wafer without an intervening adhesive. Directly bonding without an adhesive is described throughout U.S. Pat. Nos. 7,126,212; 8,153,505; 7,622,324; 7,602,070; 8,163,373; 8,389,378; 7,485,968; 8,735,219; 9,385,024; 9,391,143; 9,431,368; 9,953,941; 9,716,033; 9,852,988; 10,032,068; 10,204,893; 10,434,749; and 10,446,532, the contents of each of which are hereby incorporated by reference herein in their entirety and for all purposes. The skilled artisan will readily appreciate that the techniques taught in the incorporated patents can be modified by provision of a micro-structured metal layer between conductive features, by providing a metal oxide layer and reducing it as taught herein.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes. a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

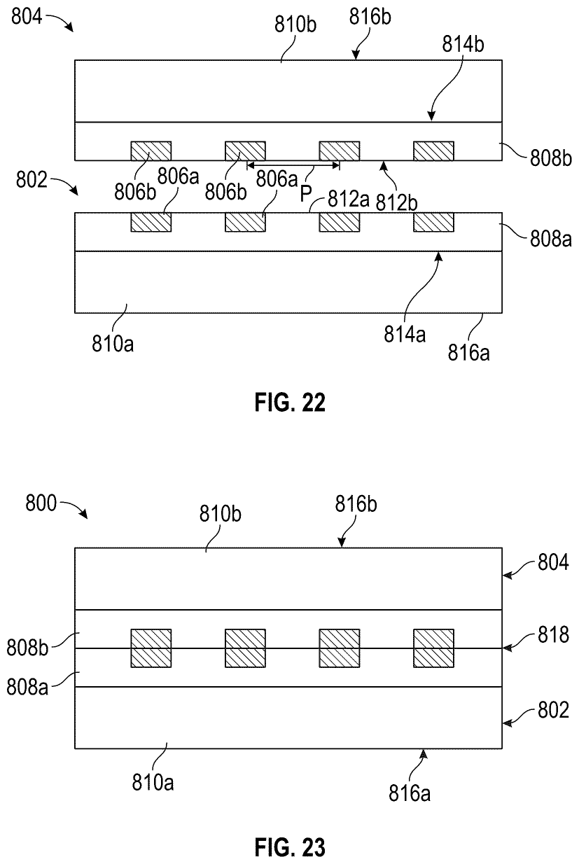

FIGS. 22 and 23 schematically illustrate cross-sectional side views of first and second elements 802, 804 prior to and after, respectively, a process for forming a directly bonded structure, and more particularly a hybrid bonded structure, according to some embodiments. In FIG. 23, a bonded structure 800 comprises the first and second elements 802 and 804 that are directly bonded to one another at a bond interface 818 without an intervening adhesive. Conductive features 806a of the first element 802 may be electrically connected to corresponding conductive features 806b of the second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed over respective front sides 814a, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 810a, 810b, and can electrically communicate with at least some of the conductive features 806a, 806b. Active devices and/or circuitry can be disposed at or near the front sides 814a, 814b of the base substrate portions 810a, 810b. and/or at or near opposite backsides 816a, 816b of the base substrate portions 810a, 810b. In other embodiments, the base substrate portions 810a, 810b may not include active circuitry, but may instead comprise dummy substrates, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 810a and 810b can be in a range of 5 ppm/° C. to 100 ppm/° C. 5 ppm/° C. to 40 ppm/° C., 10 ppm/° C. to 100 ppm/° C., or 10 ppm/° C. to 40 ppm/° C.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO3) or lithium niobate (LiNbO3), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a, 810b comprises a packaging material, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a, 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812a, 812b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. Polishing can also be tuned to leave the conductive features 806a, 806b recessed relative to the field regions of the bonding layers 808a, 808b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a bond interface 818 between the first and second elements 802, 804. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 800, the bond interface 818 between two non-conductive materials (e.g., the bonding layers 808a, 808b) can comprise a very smooth interface with higher nitrogen (or other terminating species) content and/or fluorine concentration peaks at the bond interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 808a and 808b can be directly bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding field regions, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a, 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 22 prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the feature, and so can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 806a, 806b across the direct bond interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 806a and 806b to one of the lateral dimensions (e.g., a diameter) of the bonding pad is less than is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the bond interface 818. In some embodiments, the metal is or includes copper, which can have grains oriented along the 111 crystal plane for improved copper diffusion across the bond interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

In one aspect, a process is provided for preparing an element for hybrid bonding. The process includes providing a metal oxide layer over a conductive feature, where the conductive feature is at least partially embedded in a dielectric material and the conductive feature and the dielectric material form a bonding layer of a first element. The process also includes chemically reducing the metal oxide layer to form a metal layer. A bonding surface of the bonding layer of the first element is prepared for hybrid bonding to a second element.

In some embodiments, the metal oxide layer includes metal oxide grains. The metal oxide layer can include an oxide of a metal of the conductive feature, and the metal layer can include a layer of a metal of the conductive feature. In some embodiments, the metal layer is more conductive than the metal oxide layer. In some embodiments, a metal of the conductive feature and a metal in the metal oxide layer include at least one of copper, nickel, gold, indium, molybdenum, cobalt, zinc, tungsten, tantalum, titanium, aluminum, copper, nickel, chromium, gold, indium, tin, platinum, silver, ruthenium, molybdenum, palladium, cobalt, zinc, tungsten, tantalum, titanium, or aluminum. In some embodiments, the metal layer comprises nanograins, where the nanograins have an average dimension in the range of about 2 nm to 100 nm. The nanograins can have an average dimension in the range of about 8 nm to 80 nm, or the nanograins can have an average dimension in the range of about 5 nm to 60 nm.

In some embodiments, the process also includes, before providing the metal oxide layer over the conductive feature, forming a recess in the conductive feature relative to an upper surface of the bonding layer. A depth of the recess can be in the range of about 5 nm to 100 nm relative to the upper surface.

In some embodiments, providing the metal oxide layer over the conductive feature includes oxidizing a conductive material disposed over the dielectric material and oxidizing a part of the conductive feature. In some embodiments, providing the metal oxide layer over the conductive feature includes oxidizing a layer of the conductive feature. The oxidizing process can include plasma oxidation, thermal oxidation, or wet oxidation. In other embodiments, providing the metal oxide layer over the conductive feature includes sputtering the metal oxide layer onto the conductive feature, spin-coating the metal oxide layer onto the conductive feature, electrolytic or electroless deposition, or depositing the metal oxide layer by chemical vapor deposition (CVD), atomic layer deposition (ALD), or wet processing methods.

In some embodiments, chemically reducing the metal oxide layer includes exposing the first element to a reducing environment. The reducing environment can include a hydrogen-containing plasma, a water vapor plasma, or a forming gas.

In some embodiments, preparing the bonding surface includes planarizing the bonding surface. Preparing the bonding surface can also include activating a surface of the dielectric material.

In another aspect, a process for hybrid bonding is provided. The process includes providing a metal oxide layer over a first conductive feature, where the first conductive feature is at least partially embedded in a first dielectric material, and the first conductive feature and the first dielectric material forma first bonding layer of a first element. The process also includes chemically reducing the metal oxide layer to form a metal layer. A first bonding surface of the first bonding layer of the first element is prepared for hybrid bonding. The first dielectric material is directly bonded to a second dielectric material of a second element. After bonding the first dielectric material to the second dielectric material, the first element and the second element are annealed at an annealing temperature to complete a hybrid bond between the first conductive feature of the first element and a second conductive feature of the second element.

In some embodiments, the first conductive feature includes copper, and the annealing temperature is below about 250° C., below about 200° C., or below about 180° C.

In some embodiments, the first conductive feature and the second conductive feature include cobalt and/or molybdenum, where the metal oxide layer includes cobalt and/or molybdenum.

In some embodiments, the first element and the second element are dies. In other embodiments, the first element and the second element are wafers. In yet other embodiments, the first element includes at least one die and the second element is a wafer including at least one module, wherein the die and the module are aligned.

In another aspect, a process of fabricating a microelectronic element is provided. The process includes at least partially oxidizing a conductive feature in a bonding layer. The bonding layer forms part of the microelectronic element and includes a dielectric material surrounding the conductive feature. The conductive feature is exposed at an upper surface of the bonding layer. The process includes reducing the conductive feature after at least partially oxidizing the conductive feature. The process also includes planarizing the upper surface to prepare the bonding layer for hybrid bonding.

In some embodiments, the conductive feature includes copper, nickel, chromium, gold, indium, tin, platinum, silver, ruthenium, molybdenum, palladium, cobalt, zinc, tungsten, tantalum, titanium, aluminum, or alloys thereof.

In some embodiments, after reducing the conductive feature, a surface of the conductive feature includes nanograins.

In some embodiments, before at least partially oxidizing the conductive feature, a recess is formed in the conductive feature relative to the upper surface of the bonding layer.

In still another aspect, a method is provided for fabricating a device. The method includes providing the device with a base substrate and a hybrid bonding layer disposed over the base substrate, where the hybrid bonding layer has at least one conductive feature at least partially embedded in a dielectric material. The conductive feature is exposed at an upper surface. The method also includes converting a top layer of the conductive feature to an oxidized layer. The oxidized layer is converted to a metal layer.

In some embodiments, the metal layer include nanograins.

In some embodiments, the base substrate includes single crystal semiconductor material, an interposer, a semiconductor package, a flat panel, a dielectric substrate, a MEMS device, or a passive device.

In some embodiments, the method also includes directly bonding the device to an external device to form a bonded structure. After bonding, the bonded structure is annealed at an annealing temperature.

In still another aspect, a process is provided for preparing a first element for hybrid bonding to a second element. The process includes providing or forming a metal compound layer over a conductive feature, where the conductive feature is at least partially embedded in a dielectric material, and the conductive feature and the dielectric material forms a bonding layer of the first element. The process also includes reducing the metal compound layer to form a metal layer. A bonding surface of the bonding layer is prepared for hybrid bonding.

In some embodiments, the metal compound layer includes a metal oxide, a metal nitride, a metal fluoride, a metal gluconate, or a metal amide. The metal layer can include nanograins of a metal.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g., ” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A process for preparing a first element for hybrid bonding, the process comprising:
providing a metal oxide layer over a conductive feature, wherein the conductive feature is at least partially embedded in a dielectric material, the conductive feature and the dielectric material forming a bonding layer of the first element;
chemically reducing the metal oxide layer to form a metal layer; and
preparing a bonding surface of the bonding layer of the first element for hybrid bonding to a second element.

2. The process of claim 1, wherein the metal oxide layer comprises metal oxide grains.

3. The process of claim 1, wherein the metal oxide layer comprises an oxide of a metal of the conductive feature.

4. The process of claim 1, wherein the metal layer comprises a layer of a metal of the conductive feature.

5. The process of claim 1, wherein the metal layer is more conductive than the metal oxide layer.

6. The process of claim 1, wherein a metal of the conductive feature and a metal in the metal oxide layer comprise at least one of copper, nickel, gold, indium, molybdenum, cobalt, zinc, tungsten, tantalum, titanium, aluminum, copper, nickel, chromium, gold, indium, tin, platinum, silver, ruthenium, molybdenum, palladium, cobalt, zinc, tungsten, tantalum, titanium, or aluminum.

7. The process of claim 1, wherein the metal layer comprises nanograins.

8. The process of claim 7, wherein the nanograins have an average dimension in the range of about 2 nm to 100 nm.

9.-10. (canceled)

11. The process of claim 1, further comprising, before providing the metal oxide layer over the conductive feature, forming a recess in the conductive feature relative to an upper surface of the bonding layer.

12. The process of claim 11, wherein a depth of the recess is in the range of about 1 nm to 100 nm relative to the upper surface.

13. The process of claim 1, wherein providing the metal oxide layer over the conductive feature comprises oxidizing a conductive material disposed over the dielectric material and oxidizing a part of the conductive feature.

14. The process of claim 1, wherein providing the metal oxide layer over the conductive feature comprises oxidizing a layer of the conductive feature.

15.-17. (canceled)

18. The process of claim 1, wherein providing the metal oxide layer over the conductive feature comprises sputtering the metal oxide layer onto the conductive feature.

19. The process of claim 1, wherein providing the metal oxide layer over the conductive feature comprises spin-coating the metal oxide layer onto the conductive feature.

20. The process of claim 1, wherein providing the metal oxide layer over the conductive feature comprises electrolytic or electroless deposition.

21. The process of claim 1, wherein providing the metal oxide layer over the conductive feature comprises depositing the metal oxide layer by chemical vapor deposition (CVD), atomic layer deposition (ALD), or wet processing methods.

22. The process of claim 1, wherein chemically reducing the metal oxide layer comprises exposing the first element to a reducing environment.

23.-28. (canceled)

29. A process for hybrid bonding, the process comprising:
providing a metal oxide layer over a first conductive feature, wherein the first conductive feature is at least partially embedded in a first dielectric material, the first conductive feature and the first dielectric material forming a first bonding layer of a first element;
chemically reducing the metal oxide layer to form a metal layer;
preparing a first bonding surface of the first bonding layer of the first element for hybrid bonding;
directly bonding the first dielectric material to a second dielectric material of a second element; and
after bonding the first dielectric material to the second dielectric material, annealing the first element and the second element at an annealing temperature to complete a hybrid bond between the first conductive feature of the first element and a second conductive feature of the second element.

30. The process of claim 29, wherein the first conductive feature comprises copper, and wherein the annealing temperature is below about 250° C.

31.-32. (canceled)

33. The process of claim 29, wherein the first conductive feature and the second conductive feature comprise metal.

34.-52. (canceled)

53. A method of fabricating a device, the method comprising:
providing the device having a base substrate and a hybrid bonding layer disposed over the base substrate, the hybrid bonding layer having at least one conductive feature at least partially embedded in a dielectric material, the at least one conductive feature being exposed at an upper surface;
converting a top layer of the at least one conductive feature to an oxidized layer; and
converting the oxidized layer to a metal layer.

54. The method of claim 53, wherein the metal layer comprises nanograins.

55.-66. (canceled)
